(19) United States
(12) Patent Application Publication
(10) Pub. No.: US 2024/0021980 A1
(43) Pub. Date: Jan. 18, 2024

(54) CONNECTOR-LESS PRINTED CIRCUIT BOARD MOUNTED ANTENNA

(71) Applicant: Mobix Labs, Inc., Irvine, CA (US)

(72) Inventors: Meysam Moallem, Irvine, CA (US); Saeideh Shad, Irvine, CA (US)

(21) Appl. No.: 18/351,262

(22) Filed: Jul. 12, 2023

Related U.S. Application Data
(60) Provisional application No. 63/388,281, filed on Jul. 12, 2022.

(51) Int. Cl. H01Q 1/36; H01Q 9/27; H01Q 21/06; H05K 1/18

(52) U.S. Cl. CPC H01Q 1/36; H01Q 9/27; H01Q 21/061; H05K 1/181; H05K 2201/10098

(57) ABSTRACT

Antenna-on-printed circuit board assembly has a printed circuit board with at least one mounting edge segment and an antenna module. One or more individual antenna elements are laid out on an antenna module substrate having at least one overhang segment. The antenna module is suspended from the printed circuit board with the at least one overhang segment overlapping with and fixed to a corresponding one of the at least one mounting edge segment.

### CROSS-REFERENCE TO RELATED APPLICATIONS

This application relates to and claims the benefit of U.S. Provisional Application No. 63/388,281 filed Jul. 12, 2022 and entitled “CONNECTOR-LESS PCB-MOUNT ANTENNA,” the entire disclosure of which is wholly incorporated by reference herein.

### STATEMENT RE: FEDERALLY SPONSORED RESEARCH/DEVELOPMENT

Not Applicable

### BACKGROUND

### 1. Technical Field

The present disclosure relates generally to antennas for wireless transmission and reception, and more particularly to connector-less printed circuit board mounted antennas.

### 2. Related Art

At its most basic level, an antenna functions to transduce electrical signals to electromagnetic signals for transmission over the air, and to transduce electromagnetic signals received over the air to electrical signals. One conventional application is a radio frequency communication system that comprises a transmitter and a receiver each with respective transmit and receive antennas. A signal containing information is modulated with a radio frequency carrier wave and passed to the antenna. The antenna, in turn, radiates the transmission signal via the transmit antenna. The radio frequency signal is propagated over the air, which is then transduced or converted back to an electrical signal by the receive antenna some distance away. The receiver may include additional circuitry that removes the radio frequency carrier wave and extracts information from the underlying electrical signal.

A simple bi-directional wireless communication system may incorporate a single antenna at each communication node with each antenna serving both transmission and reception functions. However, it is also possible to use multiple antennas at both the transmission and reception ends to increase capacity density and throughput. Also referred to as Multiple Input, Multiple Output (MIMO), a series of antennas may be arranged in a single or multi-dimensional array, and further, may be employed for beamforming where radio frequency signals are shaped to point in a specified direction of the receiving device. A single transmitter circuit can feed the signal to each of the antennas individually through splitters, with the phase of the signal as radiated from each of the antennas being varied over the span of the array. There are variations in which multiple transmitter circuits feed each antenna or a group of antennas. The collective signal radiated from the individual antennas may have a narrower beam width, and the direction of the transmitted beam may be adjusted based upon the constructive and destructive interferences of the signals radiated from each antenna resulting from the phase shifts. Beamforming may be used in both transmission and reception, and the spatial reception sensitivity may likewise be adjusted.

In addition to such radio frequency communications systems, antenna arrays may be utilized in synthetic aperture radar (SAR) imaging systems in which electromagnetic waves transmitted against a target surface and the waves reflected therefrom are collected to build a representation of the target surface. A single beam-forming antenna comprising multiple antenna elements may be moved along the target by way of a moving platform such as an aircraft or a spacecraft. In this context, the synthetic aperture is understood to refer to the enlargement of the antenna aperture resulting from its movement over a wider target area. A higher spatial resolution is understood to be possible despite the smaller physical size of the antenna. Typical SAR operating frequencies span the radio frequency and microwave range of the electromagnetic spectrum, and include the P-band, L-Band, S-band, C-band, and the X-band, depending on the specific imaging application and wave penetration requirements.

These applications typically require circularly polarized ultra-wideband antennas. The application for ultrawideband antennas also includes satellite navigation systems, and surveillance systems, as well as electronic counter measures (ECM) and electronic counter-countermeasures (ECCM). In order to achieve desired performance specifications, it is necessary of the antennas to have a specific structure and stack-up that may not necessarily be suitable for surface mounting on a printed circuit board, or for integration with the printed circuit board. Accordingly, there is a need in the art for an improved, low-cost and low-profile antenna with a more simplified overall structure and improved feeding configurations. It would be desirable for the antennas to achieve unidirectional radiation patterns while maintaining circular polarization and impedance matching over an ultrawide bandwidth.

Antennas are typically connected or attached to an underlying printed circuit board with RF connectors, though such connectors increase overall module costs and can negatively impact performance parameters such as insertion loss. Thus, there is also a need in the art for a connector-less coupling of the antenna for improved integration with the radio frequency module.

### BRIEF SUMMARY

This disclosure provides various embodiments of an antenna-on-printed circuit board assembly, including various printed circuit board/antenna module structures, connector-less antenna to printed circuit board transition elements, and ultra-wide band antenna modules. In one embodiment, an antenna-on-printed circuit board assembly may include a printed circuit board and an antenna module. The printed circuit board may define at least one mounting edge segment. The antenna module may include one or more individual antenna elements laid out on an antenna module substrate having at least one overhang segment. The antenna module may be suspended from the printed circuit board with at least one overhang segment overlapping with and fixed to a corresponding one of the at least one mounting edge segment.

An antenna assembly is disclosed in accordance with another embodiment. The antenna assembly may include an antenna substrate. There may also be one or more first Archimedean spiral elements, each with a center and a first element distal end, along with one or more second Archimedean spiral elements, each also having a center and a second element distal end. The antenna assembly may include a transmission line that extends to the center of each of the one or more first Archimedean spiral elements and the one or more second Archimedean spiral elements. There may be a low dielectric constant foam sheet underneath the antenna substrate, an absorber sheet underneath the low dielectric constant foam sheet, and a conductive layer underneath the absorber sheet.

According to another embodiment of the present disclosure, there may be an antenna-on-printed circuit board assembly. The assembly may include a main printed circuit board with one or more connecting conductive traces and printed circuit board-side microstrip-to-microstrip transition structures connected to each. There may also be an antenna module with one or more individual antenna elements laid out on an antenna module substrate. The antenna module may also include one or more connecting transmission lines for each and connected to antenna-side microstrip-to-microstrip transition structures. The antenna module may be attached to the printed circuit board with the printed circuit board-side transition microstrip.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A is a perspective view of a first embodiment of an antenna-on-printed circuit board assembly with an antenna module separated from the printed circuit board;

FIG. 1B is a perspective view of the first embodiment of the antenna-on-printed circuit board assembly with the antenna module mounted to the printed circuit board;

FIG. 2 is a cross-sectional view of the first embodiment of the antenna-on-printed circuit board assembly with the antenna module mounted to the printed circuit board with fasteners;

FIG. 3 is a cross-sectional view of the first embodiment of the antenna-on-printed circuit board assembly with the antenna module soldered onto the printed circuit board;

FIG. 4A is a perspective view of a second embodiment of an antenna-on-printed circuit board assembly with an antenna module separated from the printed circuit board;

FIG. 4B is a perspective view of the second embodiment of the antenna-on-printed circuit board assembly with the antenna module mounted to the printed circuit board;

FIG. 5A is a perspective view of a third embodiment of an antenna-on-printed circuit board assembly with an antenna module separated from the printed circuit board;

FIG. 5B is a perspective view of the third embodiment of the antenna-on-printed circuit board assembly with the antenna module mounted to the printed circuit board;

FIG. 6A is a perspective view of a first embodiment of an antenna-on-printed circuit board assembly with an antenna module separated from the printed circuit board;

FIG. 6B is a perspective view of the first embodiment of the antenna-on-printed circuit board assembly with the antenna module mounted to the printed circuit board;

FIG. 7A is a perspective view of a transition interconnect that may be utilized in the various embodiments of the antenna-on-printed circuit board assembly with an antenna side shown separated and flipped from a printed circuit board side;

FIG. 7B is a perspective view of the constructed transition interconnect;

FIG. 8 is a graph plotting the measured return loss and loss performance parameters of the transition interconnect;

FIG. 9 is a detailed perspective view of the antenna module;

FIG. 10 is a perspective view of one antenna element of the antenna module and illustrating the various layers thereof;

FIG. 11 is a plan view of the antenna element showing the Archimedean spiral elements;

FIG. 12 is a top plan view of an alternative layout of a top layer of the antenna module;

FIG. 13 is a bottom plan view of the alternative layout of a bottom layer of the antenna module;

FIG. 14 is a cross-sectional view of the antenna module;

FIG. 15 is a cross-sectional view of the antenna module constructed with intermediary adhesive layers;

FIG. 16 is a cross-sectional view of the antenna module constructed with bolts and nuts;

FIG. 17 is a graph plotting the measured input return losses of each of the individual antenna elements over a frequency sweep;

FIG. 18 is a graph plotting the measured isolation of each of the individual antenna elements over a frequency sweep;

FIG. 19A is a graph showing the measured radiation pattern in total gain at 10 GHz;

FIG. 19B is a graph showing the measured radiation pattern in co-polarization/cross-polarization gain at 10 GHz;

FIG. 20A is a graph showing the measured radiation pattern in total gain at 20 GHz;

FIG. 20B is a graph showing the measured radiation pattern in co-polarization/cross-polarization gain at 20 GHz;

FIG. 21A is a graph showing the measured radiation pattern in total gain at 40 GHz; and

FIG. 21B is a graph showing the measured radiation pattern in co-polarization/cross-polarization gain at 40 GHz.

### DETAILED DESCRIPTION

The detailed description set forth below in connection with the appended drawings is intended as a description of the several presently contemplated embodiments of an antenna-on-printed circuit board assembly and is not intended to represent the only form in which such embodiments may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

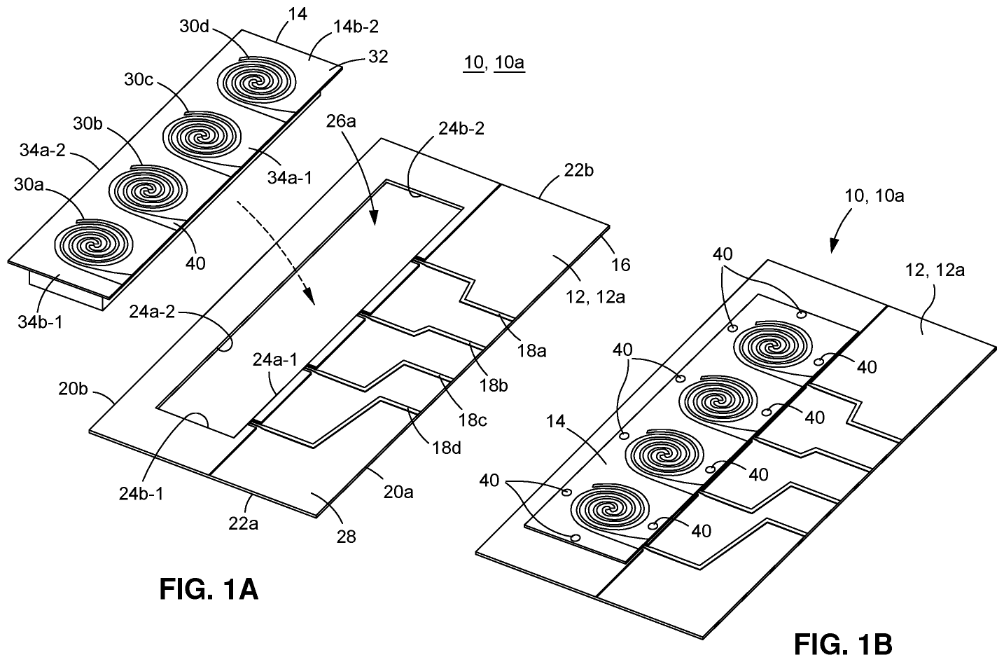

With reference to FIGS. 1A and 1B, a first embodiment of an antenna-on-printed circuit board assembly 10a may comprise a printed circuit board 12 and an antenna module 14 that is mounted thereto. In further detail, the printed circuit board 12 may have a flat planar structure defined by one or more sheets of non-conductive substrate 16 as well as one or more conductive layers (typically the top layer and/or the bottom layer) that are etched with patterns corresponding to the circuit layout. The illustrated example shows a series of connecting conductive traces 18a-18d on the printed circuit board 12 that electrically interconnect one circuit component to another. Conventionally, FR-4 glass epoxy is used for the substrate and copper is used for the conductive layers. Thus, the printed circuit board 12 may employ such fabrication. There are numerous variations in materials and manufacturing techniques that are deemed to be within the purview of those having ordinary skill in the art, and such details will be omitted for the sake of brevity.

The first embodiment of the printed circuit board 12a may be quadrangular and further be defined by a pair of opposed longitudinal edges 20a and 20b, and a pair of opposed lateral edges 22a, 22b perpendicular thereto. The example is only intended to illustrate how the antenna module 14 may be mountable to a printed circuit board 12a with a portion configured as shown. The overall printed circuit board structure may extend in lateral or longitudinal direction, and such an extended circuit board may be quadrangular or any other shape. One embodiment of the printed circuit board 12a may define a first variation of a through-hole 26a within the confines or boundaries thereof, e.g., inside the longitudinal edges 20a, 20b, and lateral edges 22a, 22b. To this end, the printed circuit board 12a further defines at least one mounting edge segment 24, which in this embodiment, includes opposed longitudinal mounting edge segments 24a-1 and 24a-2, and opposed lateral mounting edge segments 24b-1 and 24b-2. The longitudinal mounting edge segment 24a-1 is parallel to and faces the longitudinal edge 20a of the printed circuit board 12a, while the longitudinal mounting edge segment 24a-2 is parallel to and faces the longitudinal edge 20b of the printed circuit board 12a. Likewise, the lateral mounting edge segment 24b-1 is parallel to and faces the lateral edge 22a, and the lateral mounting edge segment 24b-2 is parallel to and faces the lateral edge 22b. The printed circuit board 12a is defined by a top surface 28, but in some embodiments the mounting edge segments 24 may be recessed relative to the top surface 28. In other embodiments, the mounting edge segments 24 may be parallel with the top surface 28.

The antenna module 14 includes one or more individual antenna elements 30. In the illustrated examples of FIGS. 1A and 1B, there is a first antenna element 30a, a second antenna element 30b, a third antenna element 30c, and a fourth antenna element 30d. It is understood that the antenna module 14 may include any number of individual antenna elements 30 without departing from the scope of the present disclosure. Although additional details regarding the antenna elements 30 will be described below, in various exemplary embodiments, the antenna elements 30 are arranged in a single row and spaced apart from each other to define the overall surface area of the antenna module 14. The antenna elements 30 may also be implemented on a printed circuit board substrate 32 with laminated conductive and non-conductive layers. As the antenna module 14 is envisioned to be mounted on to the printed circuit board 12, and specifically within the through-hole 26, the substrate 32 is sized and configured to fit within the dimensional constraints thereof. Additional details of the interconnection between the antenna elements 30 and the printed circuit board 12a will be set forth below.

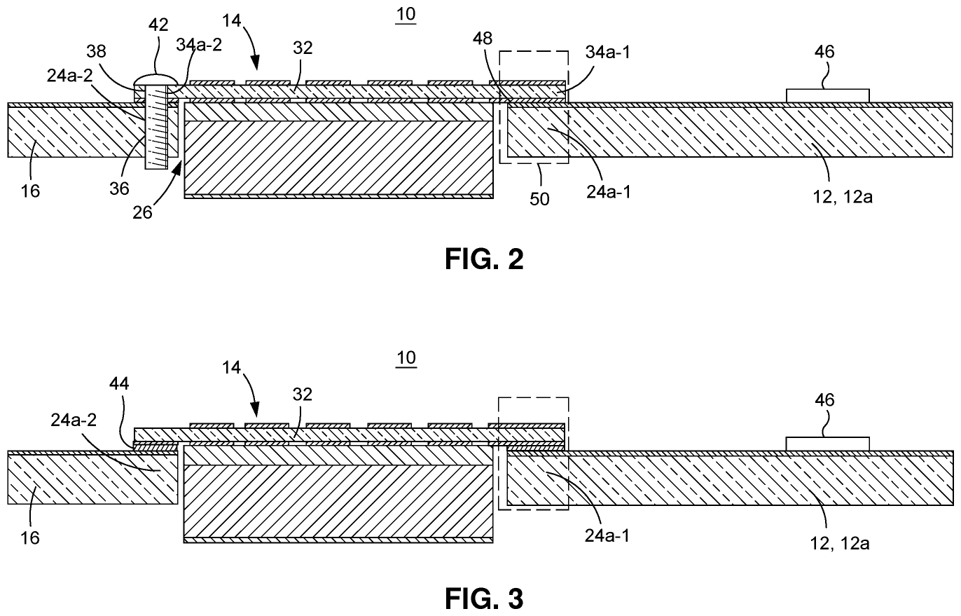

The cross-sectional view of FIGS. 2 and 3 further illustrates the features of the antenna module 14 and how it is mounted to the printed circuit board 12a. The antenna module 14, and specifically the substrate 32 thereof, defines at least one overhang segment 34. In the illustrated example, there is a first longitudinal overhang segment 34a-1 and a parallel, opposed second longitudinal overhang segment 34a-2. Furthermore, there is a first lateral overhang segment 34b-1 and a parallel, opposed second lateral overhang segment 34b-2. The antenna module 14 is suspended from the printed circuit board 12a with the at least one overhang segment overlapping with and fixed to a corresponding one of the at least one mounting edge segment 24.

With the first embodiment of the antenna-on-printed circuit board assembly 10a, the first longitudinal overhang segment 34a-1 of the antenna module 14 overlaps and is fixed to the first longitudinal mounting edge segment 24a-1 of the printed circuit board 12a, and the second longitudinal overhang segment 34a-2 overlaps and is fixed to the second longitudinal mounting edge segment 24a-2. Likewise, the first lateral overhang segment 34b-1 of the antenna module 14 overlaps and is fixed to the first lateral mounting edge segment 24b-1, and the second lateral overhang segment 34b-2 overlaps and is fixed to the second lateral mounting edge segment 24b-2.

A variety of modalities may be utilized to secure the antenna module 14 to the printed circuit board 12. FIG. 2 illustrates an embodiment in which fasteners are used. In further detail, both the printed circuit board substrate 16 and the antenna module substrate 32 may define a set of through-holes 36, 38 along the mounting edge segment(s) 24 and overhang segments 34, respectively, at one or more fixation locations 40 around the antenna module 14/printed circuit board 12. The through-holes 36 on the mounting edge segments 24 of the printed circuit board 12 are understood to be in axial alignment with a respective one of the through-holes 38 on the overhang segments 34 of the antenna module 14, such that a bolt or threaded screw 42 may be inserted through both. The head of the screw 42 may be disposed toward the top surface, with a nut being threaded onto the screw 42. Alternatively, the through-hole 36 and/or the through-hole 38 may have matching threading with the screw 42 to hold the printed circuit board 12 and the antenna module 14 together.

In the alternative embodiment illustrated in FIG. 3, the antenna module substrate may be fixed to the printed circuit board 12a by being soldered together. Thus, there may be a thin layer of solder 44 between the antenna module substrate 32 and the printed circuit board substrate 16. The soldered locations are also understood to be along the mounting edge segments 24 of the printed circuit board 12a and the overhang segments 34 of the antenna module 14, corresponding to the same fixation locations 40 as the screw-based embodiment of FIG. 2. Instead of solder 44, the fixation modality may also be glue. The foregoing illustration of the fixation modalities is presented by way of example only and not of limitation, in that other fixation modalities may be substituted, and more than one fixation modality may be utilized in a given construction.

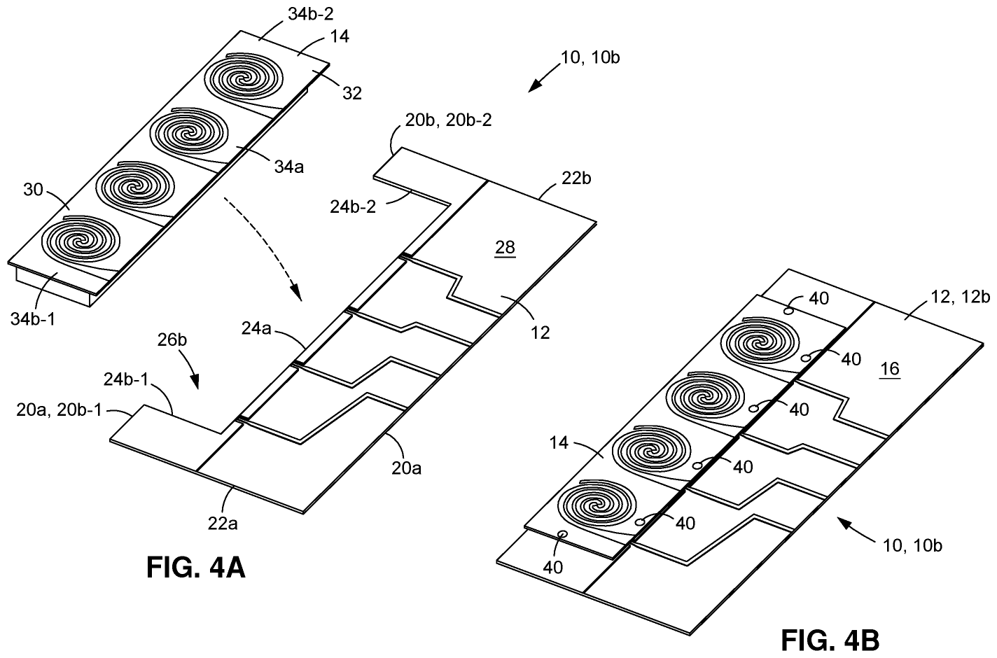

FIGS. 4A and 4B show a second embodiment of the antenna-on-printed circuit board assembly 10b that similarly comprises the printed circuit board 12 and an antenna module 14 that is mounted thereto. This embodiment, however, incorporates a printed circuit board 12b with another variant of a through-hole 26b, the details of which will be described more fully below. There are some common features with the first embodiment 12a, in that it has a flat planar structure defined by one or more sheets of non-conductive substrate 16 and one or more conductive layers that are etched with patterns corresponding to the circuit layout.

The second embodiment of the printed circuit board 12b may have a generally quadrangular shape defined by opposed longitudinal edges 20a and 20b, and a pair of opposed lateral edges 22a, 22b perpendicular thereto. The example is only intended to illustrate how the antenna module 14 may be mountable to a printed circuit board 12b with a portion configured as shown. The overall printed circuit board structure may extend in lateral or longitudinal direction, and such an extended circuit board may be quadrangular or any other shape. The second variation of the through-hole 26b is a slot extending from the longitudinal edge 20b, and so the longitudinal edge 20b is not contiguous from one lateral edge 22a to the other lateral edge 22b. To this end, there is a first section of the longitudinal edge 20b-1 and a second section of the longitudinal edge 20b-2. The printed circuit board 12b defines at least one mounting edge segment 24, and specifically the longitudinal mounting edge segment 24a that is parallel to and faces the longitudinal edge 20a. There is also defined a lateral mounting edge segment 24b-1 and an opposed and parallel lateral mounting edge segment 24b-2. The lateral mounting edge segment 24b-1 is parallel to and faces the lateral edge 22a, and the lateral mounting edge segment 24b-2 is parallel to and faces the lateral edge 22b. The printed circuit board 12b is further defined by the top surface 28, but in some embodiments the mounting edge segments 24 may be recessed relative to the top surface 28. In other embodiments, the mounting edge segments 24 may be parallel with the top surface 28. Additional details of the interconnection between the antenna elements 30 and the printed circuit board 12b will be set forth below

The antenna module 14 is understood to be the same as that in the first embodiment of the antenna-on-printed circuit board assembly 10a discussed above, so the details thereof will be omitted for the sake of brevity. In general, the substrate 32 defines at least one overhang segment 34, including the longitudinal overhang segment 34a, together with the first lateral overhang segment 34b-1 and the second lateral overhang segment 34b-2. The longitudinal segment opposite the longitudinal overhang segment 34a may not define an overhang because there is no corresponding structure on the printed circuit board 12 to which it can be mounted. The antenna module 14 is suspended from the printed circuit board 12b with the at least one overhang segment overlapping with and fixed to a corresponding one of the at least one mounting edge segment 24.

In this second embodiment of the antenna-on-printed circuit board assembly 10b, the antenna module 14 is suspended on three sides. Specifically, the longitudinal overhang segment 34a of the antenna module 14 overlaps and is fixed to the longitudinal mounting edge segment 24a of the printed circuit board 12b. The first lateral overhang segment 34b-1 of the antenna module 14 overlaps and is fixed to the first lateral mounting edge segment 24b-1, and the second lateral overhang segment 34b-2 overlaps and is fixed to the second lateral mounting edge segment 24b-2. The same modalities for securing the antenna module 14 to the printed circuit board 12 described above may be utilized, though it is to be understood that the fixing modalities are only located at the fixation locations 40 that are on those overlapping portions of the antenna module 14 and the printed circuit board 12.

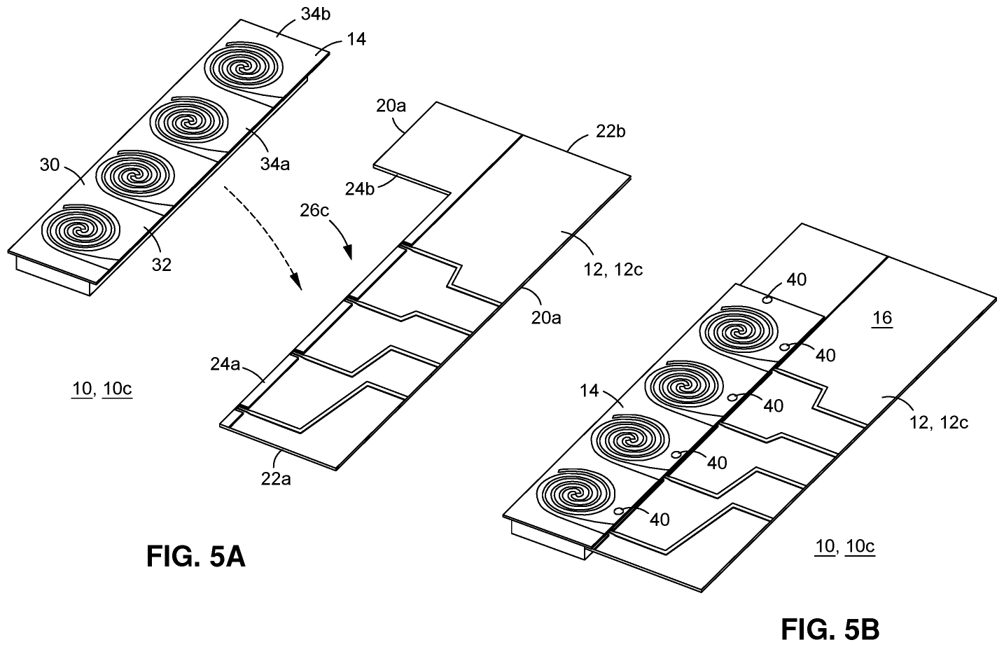

A third embodiment of the antenna-on-printed circuit board assembly 10c is shown in FIGS. 5A and 5B, and similarly comprises the printed circuit board 12 and an antenna module 14 that is mounted thereto. This embodiment incorporates a third embodiment of the printed circuit board 12c with another variant of a through-hole 26c. Again, some features are common with the first embodiment 12a and the second embodiment 12b, including its flat planar structure defined by one or more sheets of non-conductive substrate 16 and one or more conductive layers that are etched with patterns corresponding to the circuit layout.

The third embodiment of the printed circuit board 12c may have a generally quadrangular shape defined by opposed longitudinal edges 20a and 20b, and a pair of opposed lateral edges 22a, 22b perpendicular thereto. The example is only intended to illustrate how the antenna module 14 may be mountable to a printed circuit board 12c with a portion configured as shown. The overall printed circuit board structure may extend in lateral or longitudinal direction, and such an extended circuit board may be quadrangular or any other shape. The third variation of the through-hole 26c is a slot extending from the longitudinal edge 20b and the lateral edge 22a, and so the longitudinal edge 20b does not extend from one lateral edge 22a to the other lateral edge 22b. The printed circuit board 12c defines at least one mounting edge segment 24, and specifically the longitudinal mounting edge segment 24a that is parallel to and faces the longitudinal edge 20a, and a lateral mounting edge segment 24b that is parallel to and faces the lateral edge 22b.

The antenna module 14 is understood to be the same as that in the first and second embodiments of the antenna-on-printed circuit board assembly 10a, 10b discussed above. In general, the substrate 32 defines at least one overhang segment 34, including the longitudinal overhang segment 34a and the lateral overhang segment 34b. The antenna module 14 is suspended from the printed circuit board 12c with at least one overhang segment overlapping with and fixed to a corresponding one of the at least one mounting edge segment 24. Neither the longitudinal segment opposite the longitudinal overhang segment 34a nor the lateral segment opposite the lateral overhang segment 34b may define an overhang because there is no corresponding structure on the printed circuit board 12 to which it can be mounted.

In this third embodiment of the antenna-on-printed circuit board assembly 10c, the antenna module 14 is suspended on two sides. The longitudinal overhang segment 34a of the antenna module 14 overlaps and is fixed to the longitudinal mounting edge segment 24a of the printed circuit board 12b. The lateral overhang segment 34b of the antenna module 14 overlaps and is fixed to the lateral mounting edge segment 24b. The same modalities for securing the antenna module 14 to the printed circuit board 12 described above may be utilized, though it is to be understood that the fixing modalities are only located at the fixation locations 40 that are on those overlapping portions of the antenna module 14 and the printed circuit board 12.

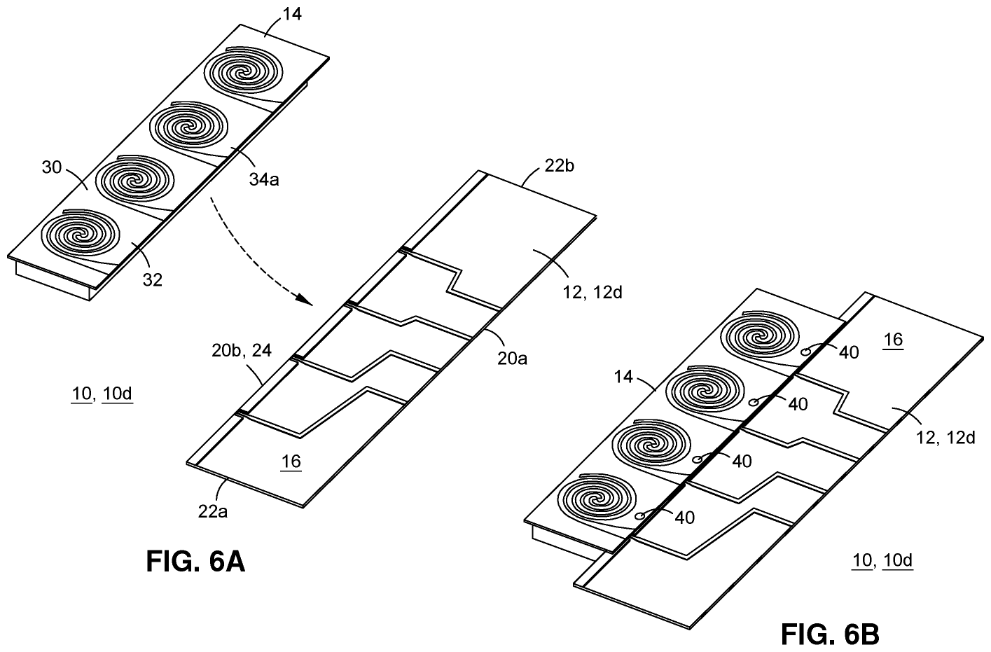

A fourth embodiment of the antenna-on-printed circuit board assembly 10d is shown in FIGS. 6A and 6B, and similarly comprises the printed circuit board 12 and an antenna module 14 that is mounted thereto. This embodiment incorporates a fourth embodiment of the printed circuit board 12d with no through-hole 26. Some features are common with the first embodiment 12a, the second embodiment 12b and the third embodiment 12c, including its flat planar structure defined by one or more sheets of non-conductive substrate 16 and one or more conductive layers that are etched with patterns corresponding to the circuit layout.

The fourth embodiment of the printed circuit board 12d may have a generally quadrangular shape defined by opposed longitudinal edges 20a and 20b, and a pair of opposed lateral edges 22a, 22b perpendicular thereto. However, this example is only intended to illustrate how the antenna module 14 may be mountable to a printed circuit board 12d with a portion configured as shown. The overall printed circuit board structure may extend in lateral or longitudinal direction, and such an extended circuit board may be quadrangular or any other shape.

The antenna module 14 is understood to be the same as that in the first, second and third embodiments of the antenna-on-printed circuit board assembly 10a, 10b, and 10c. In general, the substrate 32 defines at least one overhang segment 34, including the longitudinal overhang segment 34a. The antenna module 14 is suspended from the printed circuit board 12d with the at least one overhang segment overlapping with and fixed to a corresponding one of the at least one mounting edge segment 24. The longitudinal segment opposite the longitudinal overhang segment 34a nor the lateral segments opposite may define an overhang because there is no corresponding structure on the printed circuit board 12 to which it can be mounted.

In this fourth embodiment of the antenna-on-printed circuit board assembly 10d, the antenna module 14 is suspended on one side. The longitudinal overhang segment 34a of the antenna module 14 overlaps and is fixed to the longitudinal mounting edge segment 24 of the printed circuit board 12b. In this regard, because the printed circuit board 12d does not define any through-hole, the longitudinal mounting edge segment 24 is the longitudinal edge 20b of the printed circuit board 12d. The same modalities for securing the antenna module 14 to the printed circuit board 12 described above may be utilized. Such fixing modalities are only located at the fixation locations 40 that are on those overlapping portions of the antenna module 14 and the printed circuit board 12.

Referring back to FIGS. 1A and 2, the embodiments of the antenna-on-printed circuit board assembly 10 include connecting conductive traces 18 that interconnect the antenna module 14 and the individual antenna elements 30 thereof to a circuit component on the printed circuit board 12 such as a radio frequency integrated circuit 46. It will be appreciated that the radio frequency integrated circuit 46 may be any device that is configured to receive a radio frequency input signal from the antenna module 14 for further processing or output a radio frequency signal to the antenna module 14 for transmission over the air. Examples include front end modules with power amplifiers, low noise amplifiers, duplexers, transmitters, and receivers. Like the connecting conductive traces 18 on the printed circuit board 12, the antenna module 14 also includes connecting transmission lines 48 for each of the antenna elements 30.

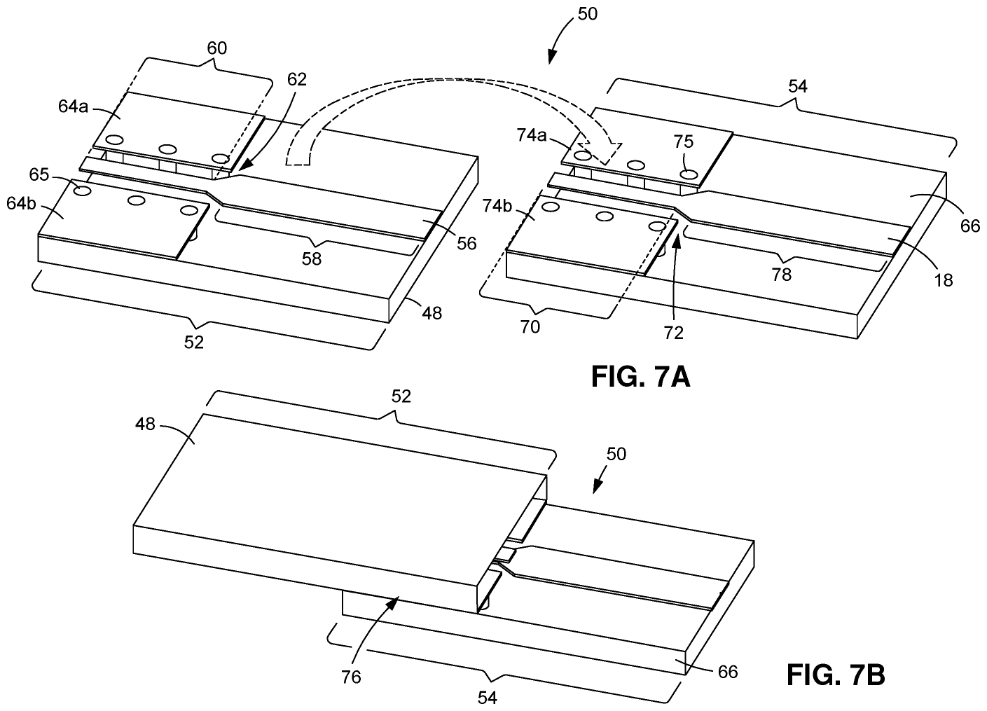

In order to electrically connect the antenna module 14 to the printed circuit board 12, a transition interconnect 50 is provided. With reference to FIGS. 7A and 7B, the transition interconnect 50 includes an antenna-side 52 as well as a printed circuit board-side 54. The antenna-side 52 includes an antenna-side microstrip line signal trace 56 with a widened section 58, a narrowed section 60, and a tapering section 62 between the widened section 58 and the narrowed section 60. Laterally adjacent to and spaced apart from the antenna-side microstrip line signal trace 56 are a pair of opposed lateral ground strips 64a, 64b that comprise metal layers on the same plane as that of the antenna-side microstrip line signal trace 56. There are a set of vias that connect the lateral ground strips 64 to the microstrip line ground plane 48, which is understood to be on a different metal layer than the antenna-side microstrip line signal trace 56 and the lateral ground strips 64.

The printed circuit board-side 54 has the same configuration, with a printed circuit board-side connecting conductive trace 18 with a widened section 68, a narrowed section 70, and a tapering section 72 between the widened section 68 and the narrowed section 70. Laterally adjacent to and spaced apart from the printed circuit board-side microstrip line signal trace 18 are a pair of opposed lateral ground strips 74a, 74b with metal layers on the same plane as that of the printed circuit board-side microstrip line signal trace 18. Vias 75 connect the lateral ground strips 74 to the microstrip line ground plane 66, which is understood to be on a different metal layer than the board-side microstrip line signal trace 18 and the ground strips 74 on the printed circuit board 12.

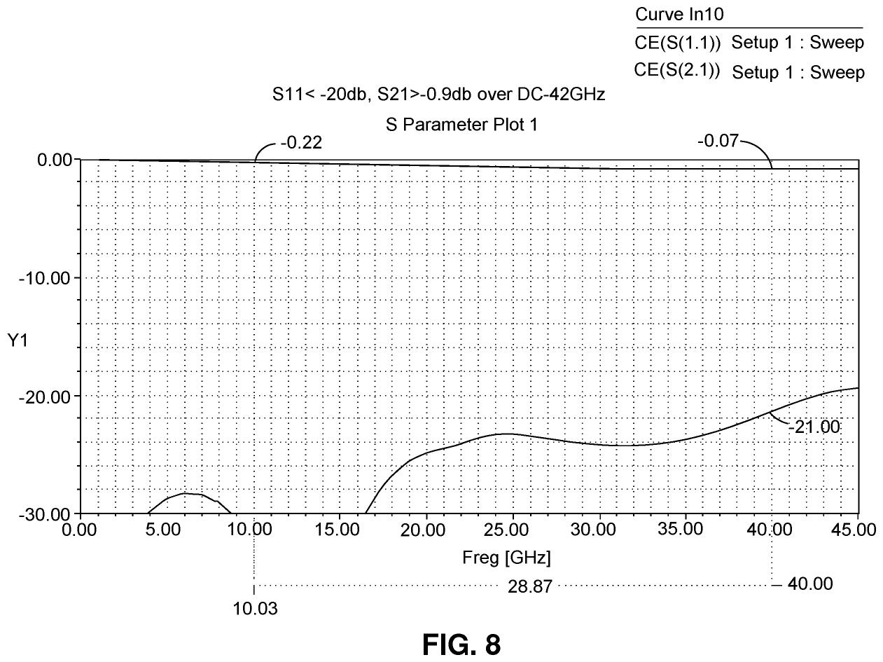

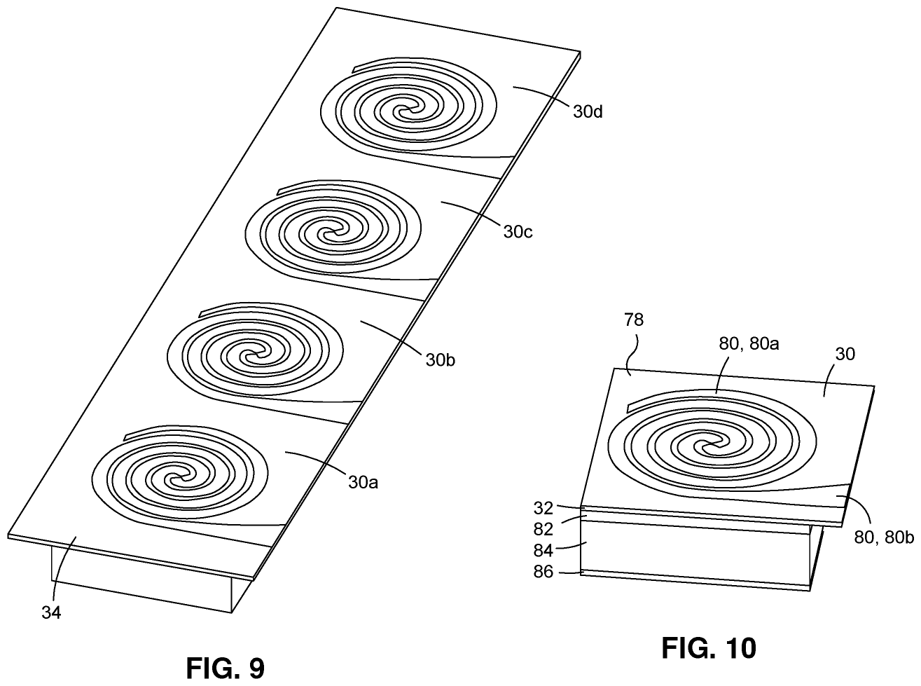

The printed circuit board-side microstrip line signal trace 18 is attached and electrically coupled to the antenna-side microstrip line signal trace 56. Additionally, the lateral ground strip 74a of the printed circuit board-side 54 is attached and electrically coupled to the lateral ground strip 64a of the antenna-side 52, and the lateral ground strip 74b of the printed circuit board-side 54 is attached and electrically coupled to the lateral ground strip 64b of the antenna-side 52. The lateral ground strips 64,74 and the narrowed sections 60, 70 may define an overlap region 76. According to one preferred, though optional embodiment, the overlap region 76 may be approximately 1.3 mm, which is envisioned to ensure a reliable electrical and mechanical connection. The antenna-side microstrip line 56 is understood to have an impedance of 50 Ohm. As shown in the graph of FIG. 8 plotting the measured input reflection coefficient or return loss S11 of the transition interconnect 50, it is less than −20 dB across the entire operating frequency range up to 42 GHz, and down to DC (0 Hz). The measured forward loss S21 remains above −0.9 dB likewise over the entire operating frequency up to 42 GHz.

As indicated above, the antenna module 14 is comprised of multiple individual antenna elements 30. In the various embodiments considered herein, and as shown in FIG. 9, the antenna module 14 includes the first antenna element 30a, the second antenna element 30b, the third antenna element 30c, and the fourth antenna element 30d arranged side-by-side in a single row. The antenna module 14 may be implemented on the antenna module substrate 32 and includes one or more conductive layers that define the radiating elements of the antenna elements 30. The substrate 32 is oversized relative to the individual antenna elements 30 to account for the aforementioned overhang segment(s) 34. In a preferred, though optional embodiment, the length of the antenna module substrate 32 is 56 mm, while its width is 11 mm. The overhang segments 34 may be between 1.5 mm to 2 mm. The separation between one antenna element 30 and an adjacent one may preferably, though optionally, be 11 mm to 18 mm.

FIG. 10 illustrates one antenna element 30 and the stacking configuration thereof. Again, the substrate 32 is at the uppermost layer, with a top surface 78 including the conductive traces constituting the radiating elements 80. In order for the antenna radiating pattern to be unidirectional, the antenna elements 30 are backed with a stack of foam, absorber, and conductor sheets. Specifically, immediately underneath the substrate 32 is a low dielectric constant/low loss foam sheet layer 82. In a preferred, though optional embodiment, this layer 82 is approximately mm to 1 mm. Immediately underneath the low dielectric constant/low loss foam sheet layer 82 is an absorber sheet layer 84, which may preferably, though optionally, have a thickness dimension of approximately 2.5 mm to 3 mm. Underneath the absorber sheet layer 84 may be a conductive layer 86 such as copper or aluminum tape. In sum, the total thickness/height dimension of the antenna module 14 may preferably, though optionally be 5 mm to 10 mm.

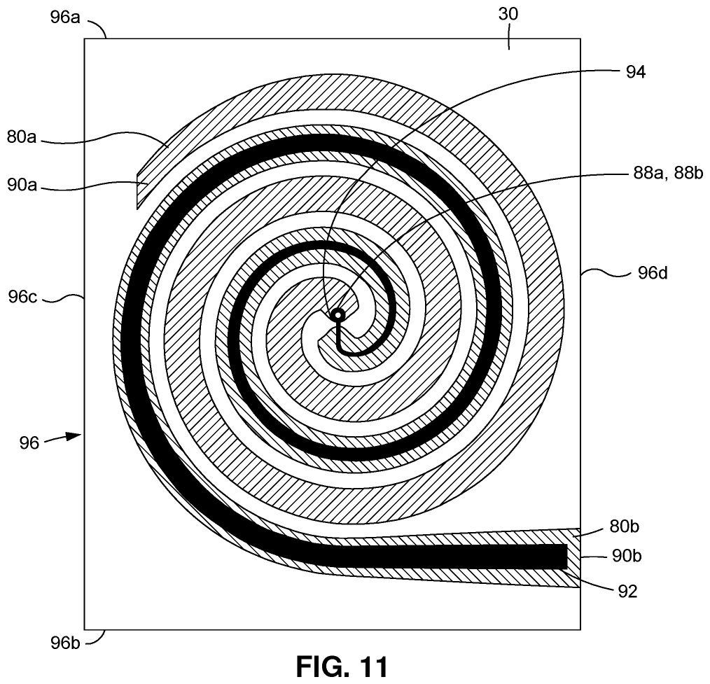

In one exemplary embodiment best shown in FIG. 11, the radiating elements 80 are shaped as Archimedean spirals, with a first Archimedean spiral 80a and a second Archimedean spiral 80b. Each of the Archimedean spirals 80a, 80b have respective centers 88a, 88b, from which the antenna is differentially fed, and respective distal ends 90a and 90b. In order to transform the single-ended microstrip line 56 to the differential feed at the center of the Archimedean spirals 80a, 80b, a planar Dyson-style balun may be implemented on the antenna module substrate 32. The Dyson-style balun comprises a trace 92, implemented on a different metal layer than the one on which the radiating elements 80 are implemented, that traces the second Archimedean spiral 80b to the center 88b thereof. The width of the trace 92 is tapered from maximum width at Archimedean spiral distal end 90b, where its impedance is 50 ohm, to the narrowest width at the center of Archimedean spirals 80a, 80b, where its impedance is 100 ohm. A via 94 at the center of the transmission line 92 and the Archimedean spiral 80a interconnect these two components.

The radiating elements 80 are confined within an antenna element area 96 bounded by a top side 96a and a bottom side 96b, along with a left side 96c and a right side 96d, with such relational terms being referenced to the view shown in FIG. 11. In this embodiment, the first Archimedean spiral 80a terminates short of the left side 96c and toward the top side 96a, while the second Archimedean spiral 80b extends to the right side 96d and toward the bottom side 96b.

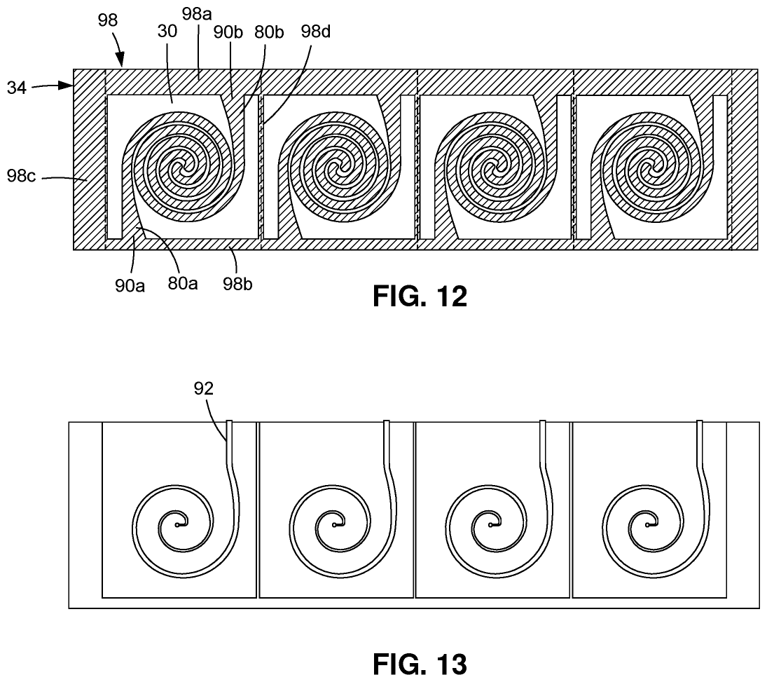

FIG. 12 illustrates an alternative layout of the Archimedean spirals 80a, 80b. The antenna element 30 generally corresponds to an antenna element area 98 bounded by a top side 98a, a bottom side 98b, a left side 98c, and a right side 98d, with such relational terms being referenced to the view shown in FIG. 12. Comparing to the antenna element area 96 shown in FIG. 11, the top side 98a is understood to correspond to the right side 96d, the bottom side 98b is understood to correspond to the left side 96c, the left side 98c is understood to correspond to the top side 96a, and the right side 98d is understood to correspond to the bottom side 96b. The top side 98a has a thicker dimension in that it corresponds to the overhang segment 34, as does the leftmost side 98c. In this alternative layout, the distal end 90a of the first Archimedean spiral 80a terminates at the bottom side 98b, and the distal end 90b of the second Archimedean spiral 80b terminates at the top side 98a. Each of the sides of the antenna element area 98 may be a conductive trace that helps shield one antenna element 30 from another.

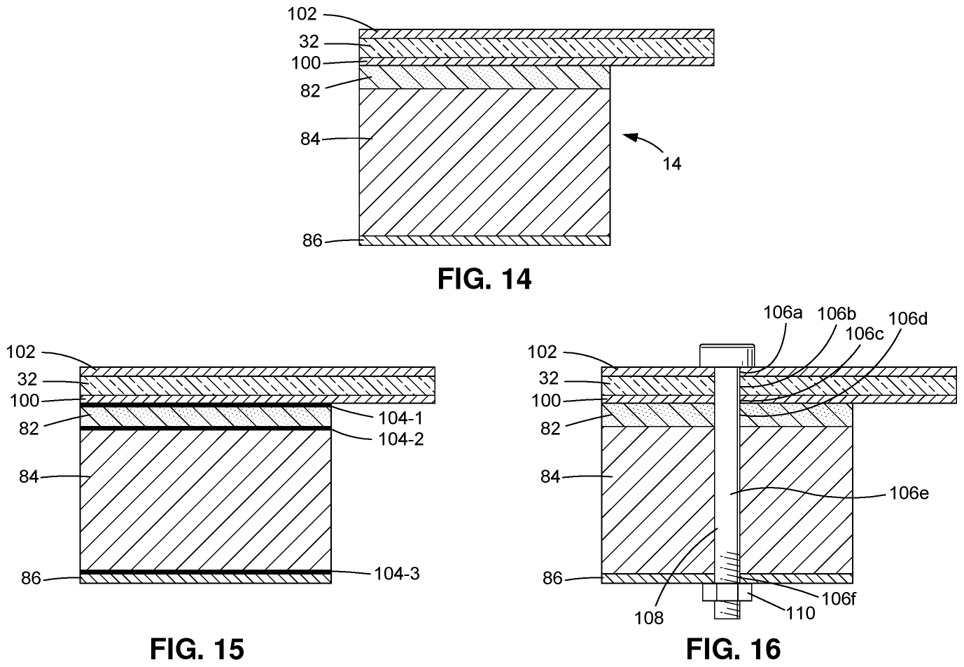

FIG. 13 illustrates the transmission line 92 that traces the path of the second Archimedean spiral 80b, though this is configured identically to the embodiment shown in FIG. 11. With additional reference to the cross-sectional view of FIG. 14, the transmission line 92 is implemented on a bottom metal layer 100 disposed underneath the substrate 32. Along these lines, the Archimedean spirals 80a, 80b, as well as the conductive traces of the sides 98, are implemented on a top metal layer 102 disposed on top of the substrate 32. This embodiment of the antenna module 14 also includes the low dielectric constant/low loss foam sheet layer 82, the absorber sheet layer 84, and the conductive layer 86.

The stack of the antenna module 14 may be constructed in accordance with various modalities. One possible implementation is the use of intermediary adhesive layers that sequentially retain/adhere one layer to another, as illustrated in FIG. 15. There is a first dual-sided adhesive layer 104-1 between the bottom metal layer 100 and the low dielectric constant/low loss foam sheet layer 82. There may also be a second dual-sided adhesive layer 104-2 between the low dielectric constant/low loss foam sheet layer 82 and the absorber sheet layer 84, and a third dual-sided adhesive layer 104-3 between the absorber sheet layer 84 and the conductive layer 86. FIG. 16 illustrates another possible implementation that contemplates the use of fasteners that compressively retain the substrate 32 and the conductive layer 86, as well as the low dielectric constant/low loss foam sheet layer 82 and the absorber sheet layer 84 in between. Specifically, each of the substrate 32 (and the top and bottom metal layers 102, 100), the low dielectric constant/low loss foam sheet layer 82, the absorber sheet layer 84, and the conductive layer 86 each define a respective through-holes 106a-106f that are coaxial. A bolt 108 is inserted through the through-holes 106 and extends a short distance out from the through-hole 106f of the conductive layer 86. The head of the bolt compresses against the substrate 32/top metal layer 102, while a nut 110 compresses against the conductive layer 86 when threaded onto the bolt 108.

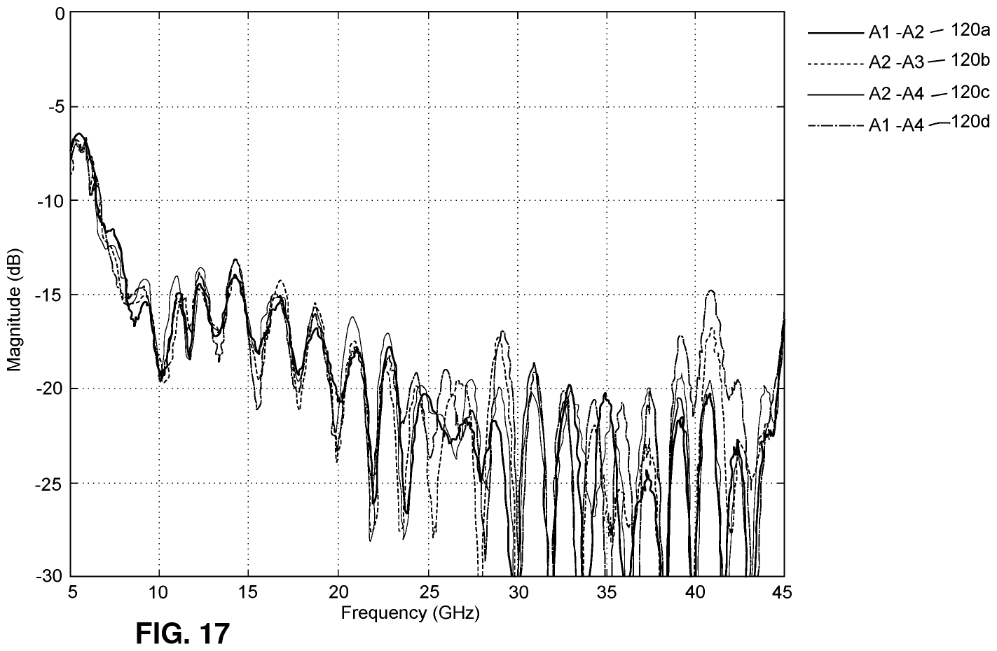

The graph of FIG. 17 plots the input reflection coefficient or return loss S11 for each of the individual antenna elements 30a-30d of connectorized antenna module 14 with alternate layout of FIG. 12 across a frequency sweep. A first plot 120a corresponds to the first antenna element 30a, a second plot 120b corresponds to the second antenna element 30b, a third plot 120c corresponds to the third antenna element 30c, and a fourth plot 120d corresponds to the fourth antenna element 30d. As shown, the return loss is less than −10 dB over an operating frequency range of 8 GHz to 45 GHz.

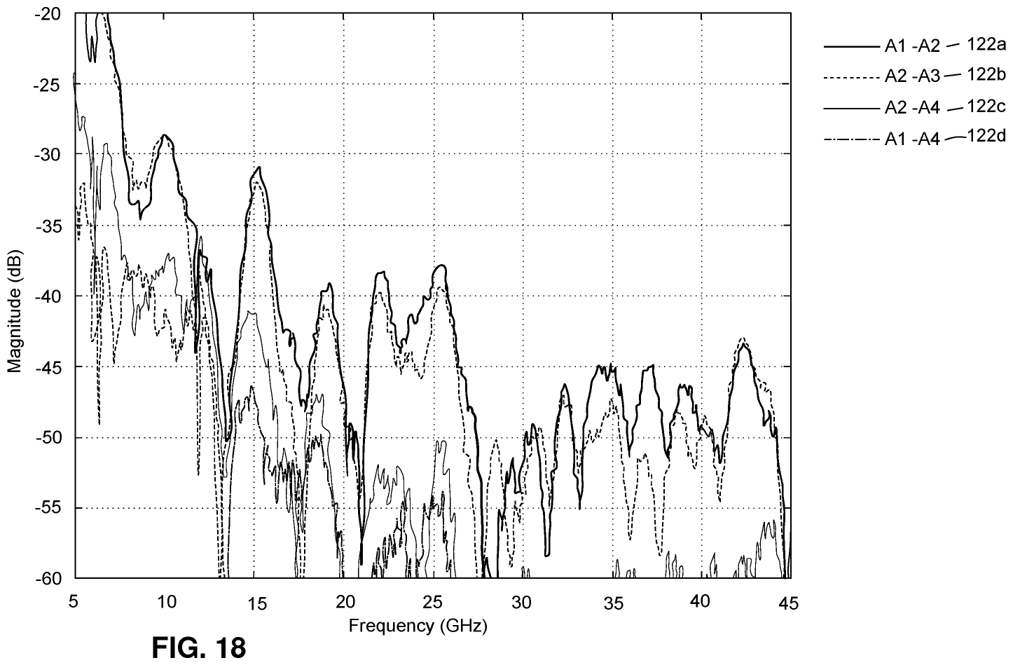

The graph of FIG. 18 plots the element-to-element isolation of various pairs of antenna elements 30. A first plot 122a shows the isolation across a frequency sweep between the first antenna element 30a and the second antenna element 30b. A second plot 122b shows the isolation across a frequency sweep between the second antenna element 30b and the third antenna element 30c. A third plot 122c shows the isolation across a frequency sweep between the third antenna element 30c and the fourth antenna element 30d. Lastly, a fourth plot 122d shows the isolation across a frequency sweep between the fourth antenna element 30d and the first antenna element 30a. As shown, the element-to-element isolation is greater than 28 dB across the operating frequency range of 8 GHz to 45 GHz.

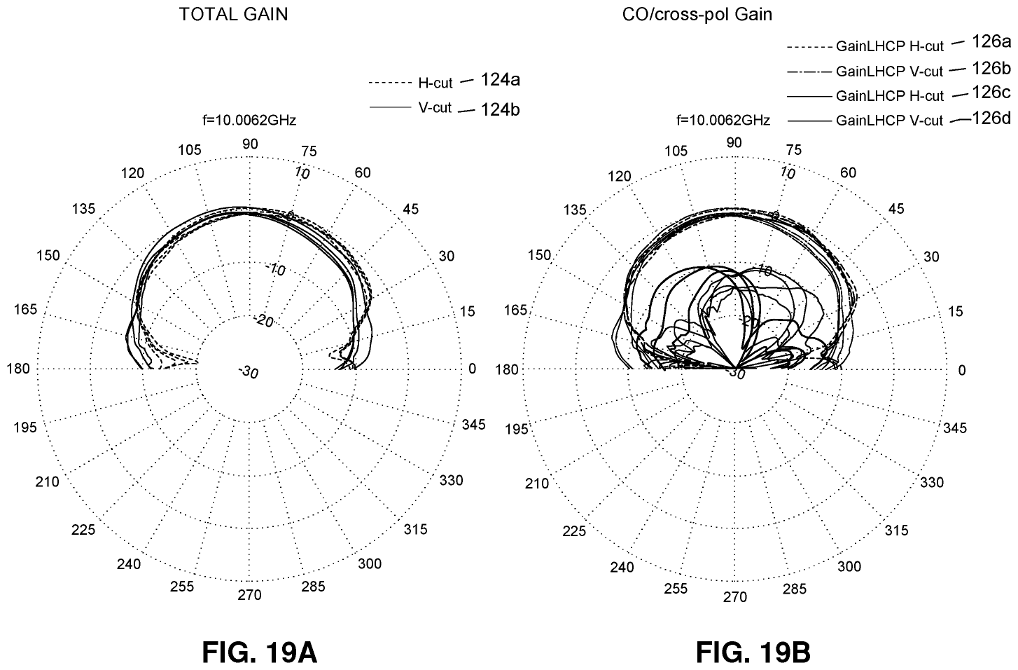

FIGS. 19A and 19B plot the measured radiation pattern of each of the antenna elements 30a-30d operating at 10 GHz. FIG. 19A plots the total gain thereof, with a first set of plots 124a corresponding to the H-cut or a plane parallel to a lateral bisection of the antenna elements 30a-30d, and a second set of plots 124b corresponding to the V-cut or a plane parallel to a longitudinal bisection of the antenna elements 30a-30d. FIG. 19B plots the co-polarization and cross-polarization gain, for both right-hand circular polarization and left-hand circular polarization. A first set of plots 126a shows the gain of left hand circular polarization along the H-cut of the antenna elements 30a-30d, and a second set of plots 126b shows the gain of left hand circular polarization along the V-cut of the elements 30a-30d. A third set of plots 126c shows the gain of right hand circular polarization along the H-cut of the antenna elements 30a30d, and a fourth set of plots 126d shows the gain of right hand circular polarization along the V-cut of the elements 30a-30d.

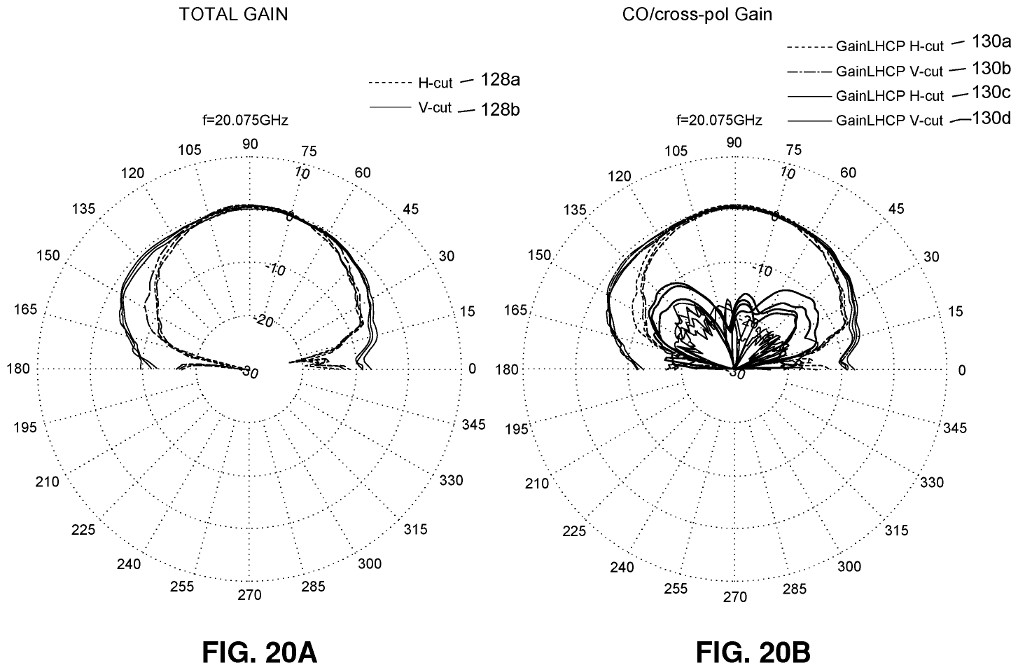

FIGS. 20A and 20B plot the measured radiation pattern of each of the antenna elements 30a-30d operating at 20 GHz. FIG. 20A plots the total gain thereof, with a first set of plots 128a corresponding to H-cut or a plane parallel to a lateral bisection of the antenna element and a second set of plots 128b corresponding to V-cut or a plane parallel to a longitudinal bisection of the antenna elements 30a-30d. FIG. 20B plots the co-polarization and cross-polarization gain, for both right-hand circular polarization and left-hand circular polarization. A first set of plots 130a shows the gain of left hand circular polarization along the H-cut of the antenna elements 30a-30d, and a second set of plots 130b shows the gain of left hand circular polarization along the V-cut of the antenna elements 30a-30d. A third set of plots 130c shows the gain of right hand circular polarization along the H-cut of the antenna elements 30a-30d, and a fourth set of plots 130d shows the gain of right hand circular polarization along the V-cut of the antenna elements 30a-30d.

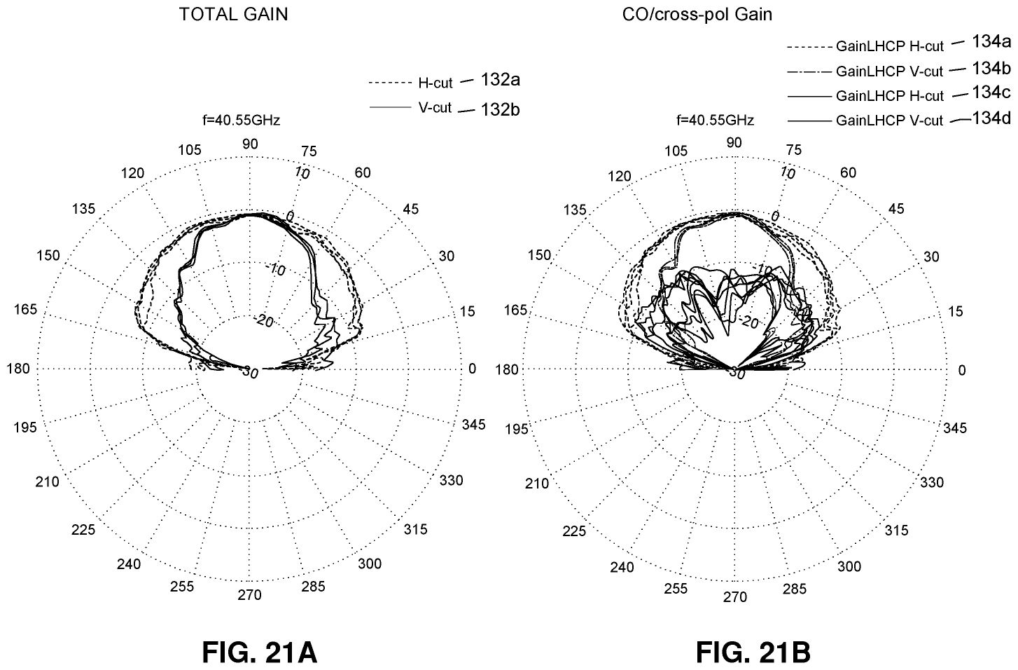

FIGS. 21A and 21B plot the measured radiation pattern of each of the antenna elements 30a-30d operating at 40 GHz. FIG. 21A plots the total gain thereof, with a first set of plots 132a corresponding to the H-cut or a plane parallel to a lateral bisection of the antenna element 30, and a second plot 132b corresponding to the V-cut or a plane parallel to a longitudinal bisection of the antenna elements 30a-30d. FIG. 21B plots the co-polarization and cross-polarization gain, for both right-hand circular polarization and left-hand circular polarization. A first set of plots 134a shows the gain of left hand circular polarization along the H-cut of the antenna elements 30a-30d, and a second set of plots 134b shows the gain of left hand circular polarization along the V-cut of the antenna elements 30a-30d. A third set of plots 134c shows the gain of right hand circular polarization along the H-cut of the antenna elements 30a-30d, and a fourth set of plots 134d shows the gain of right hand circular polarization along the V-cut of the antenna elements 30a-30d.

The particulars shown herein are by way of example and for purposes of illustrative discussion of the embodiments of the antenna-on-printed circuit board assembly and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. An antenna-on-printed circuit board assembly, comprising:
a printed circuit board defining at least one mounting edge segment; and
an antenna module including one or more individual antenna elements laid out on an antenna module substrate having at least one overhang segment, the antenna module being suspended from the printed circuit board with the at least one overhang segment overlapping with and fixed to a corresponding one of the at least one mounting edge segment.

2. The antenna-on-printed circuit board assembly of claim 1, wherein the printed circuit board defines a through hole, the at least one mounting edge segment being peripheral to the through hole.

3. The antenna-on-printed circuit board assembly of claim 2, wherein:
the through hole is defined within bounds of the printed circuit board and the at least one mounting edge segment includes a first lateral mounting edge segment and a second lateral mounting edge segment opposed thereto, and a first longitudinal mounting edge segment and a second longitudinal mounting edge segment opposed thereto;
the at least one overhang segment includes a first longitudinal overhang segment overlapping with and fixed to the first longitudinal mounting edge segment, a second longitudinal overhang segment overlapping with and fixed to the second longitudinal mounting edge segment, a first lateral overhang segment overlapping with and fixed to the first lateral mounting edge segment, and a second lateral overhang segment overlapping with and fixed to the second lateral mounting edge segment.

4. The antenna-on-printed circuit board assembly of claim 2, wherein:
the through hole is defined at an end portion of the printed circuit board and the at least one mounting edge segment includes a first lateral mounting edge segment and a second lateral mounting edge segment opposed thereto, and a first longitudinal mounting edge segment;
the at least one overhang segment includes a first longitudinal overhang segment overlapping with and fixed to the first longitudinal mounting edge segment, a first lateral overhang segment overlapping with and fixed to the first lateral mounting edge segment, and a second lateral overhang segment overlapping with and fixed to the second lateral mounting edge segment.

5. The antenna-on-printed circuit board assembly of claim 2, wherein:
the through hole is defined at a corner portion of the printed circuit board and the at least one mounting edge segment includes a first lateral mounting edge segment and a first longitudinal mounting edge segment; and
the at least one overhang segment includes a first longitudinal overhang segment overlapping with and fixed to the first longitudinal mounting edge segment and a first lateral overhang segment overlapping with and fixed to the first lateral mounting edge segment.

6. The antenna-on-printed circuit board assembly of claim 2, wherein the antenna module is fixed to the printed circuit board at a plurality of fixation locations along the at least one mounting edge segment.

7. The antenna-on-printed circuit board assembly of claim 6, wherein a fixation modality fixing the antenna module to the printed circuit board is selected from a group consisting of: soldering, screwing, and gluing.

8. The antenna-on-printed circuit board assembly of claim 1, wherein the printed circuit board includes one or more connecting transmission lines, and each of the antenna elements include a connecting transmission line.

9. The antenna-on-printed circuit board assembly of claim 8, further comprising:
one or more antenna-side radio frequency transitions connected to a corresponding one of the connecting transmission lines of a respective one of the antenna elements; and
one or more printed circuit board-side radio frequency transitions connected to a corresponding one of the one or more connecting transmission lines on the printed circuit board.

10. The antenna-on-printed circuit board assembly of claim 9, wherein each of the antenna-side radio frequency transitions are connected to a corresponding one of the printed circuit board-side radio frequency transitions.

11. The antenna-on-printed circuit board assembly of claim 9, wherein:
the one or more antenna-side radio frequency transition includes an antenna-side microstrip line signal trace and a pair of spaced apart antenna-side lateral ground strips; and
the one or more printed circuit board-side radio frequency transitions includes a printed circuit board-side microstrip line signal trace and a pair of spaced apart printed circuit board-side lateral ground strips.

12. The antenna-on-printed circuit board assembly of claim 1, wherein each of the antenna elements includes a first Archimedean spiral arm with a center and a first arm distal end, and a second Archimedean spiral arm with a center and a second arm distal end.

13. The antenna-on-printed circuit board assembly of claim 12, further comprising an absorber sheet attached to one side of the antenna elements.

14. An antenna assembly, comprising:
an antenna substrate;
one or more first Archimedean spiral elements, each having a center and a first element distal end;
one or more second Archimedean spiral elements having a center and a second element distal end;
a transmission line extending to the center of each of the one or more first Archimedean spiral elements and the one or more second Archimedean spiral elements;
a low dielectric constant foam sheet underneath the antenna substrate;
an absorber sheet underneath the low dielectric constant foam sheet; and
a conductive layer underneath the absorber sheet.

15. The antenna assembly of claim 14, further comprising:
one or more vias each connecting the centers of the first Archimedean spiral elements to the transmission line.

16. The antenna assembly of claim 14, wherein the antenna substrate defines a top surface and a bottom surface, with the one or more first Archimedean spiral elements and the one or more second Archimedean spiral elements being implemented on the top surface and the transmission line being implemented on the bottom surface.

17. The antenna assembly of claim 14, wherein the transmission line and a second Archimedean spiral element define a Dyson-style balun transforming the connecting transmission line having a first impedance to a differential feed at the centers of the first and second Archimedean spiral elements having a second impedance.

18. The antenna assembly of claim 14, further comprising adhesive layers fixing the low dielectric constant foam sheet to the antenna substrate, the low dielectric constant foam sheet to the absorber sheet, and the absorber sheet to the conductive layer.

19. The antenna assembly of claim 14, further comprising: one or more fasteners coupling the antenna substrate, the low dielectric constant foam sheet, the absorber sheet, and the conductive layer together.

20. An antenna-on-printed circuit board assembly, comprising:
a main printed circuit board with one or more connecting transmission lines and printed circuit board-side radio frequency transitions connected to each; and
an antenna module with one or more individual antenna elements laid out on an antenna module substrate and including one or more connecting transmission lines for each and connected to antenna-side radio frequency transitions, the antenna module being attached to the printed circuit board with the printed circuit board-side radio frequency transitions connected to corresponding ones of the antenna-side radio frequency transitions.

21. The antenna-on-printed circuit board assembly, wherein:
the printed circuit board defines at least one mounting edge segment; and
the antenna module defines at least one overhang segment overlapping with and fixed to a corresponding one of the at least one mounting edge segment of the printed circuit board.
